(19) United States
(12) Patent Application Publication
(10) Pub. No.: US 2026/0229551 A1
(43) Pub. Date: Aug. 6, 2026

(54) METHODS AND COMPOSITIONS FOR NANOCOMPOSITES ON ELECTRODE SURFACES

(71) Applicant: West Virginia Board of Governors on Behalf of West Virginia University, Morgantown, WV (US)

(72) Inventors: Xueyan Song, Pittsburgh, PA (US); Yun Chen, Pittsburgh, PA (US)

(21) Appl. No.: 19/124,205

(22) PCT Filed: Oct. 24, 2023
(86) PCT No.: PCT/US2023/035817

§ 371 Date: Apr. 24, 2025

Related U.S. Application Data
(60) Provisional application No. 63/418,886, filed on Oct. 24, 2022.

(51) Int. Cl. H01M 4/86; C25B 11/053; C25B 11/061; C25B 11/067; C25B 11/093; H01M 4/88; H01M 4/90; H01M 4/92

(52) U.S. Cl. CPC H01M 4/8657; H01M 4/8642; H01M 4/8867; H01M 4/9016; H01M 4/92; C25B 11/053; C25B 11/061; C25B 11/067; C25B 11/093; H01M 2004/8684

(57) ABSTRACT

In one aspect, the disclosure relates to ALD-coated electrodes comprising a conformal MnOₓ layer, and optionally, a Pt layer subjacent to the MnOₓ layer. In a further aspect, the ALD-coated electrode is an anode, e.g., a Ni/YSZ electrode. In a still further aspect, the present disclosure relates to cells comprising the disclosed ALD-coated electrodes. In a yet further aspect, the present disclosure relates to devices comprising the disclosed cells. Cells comprising the disclosed electrodes have improved stability and peak power performance. This abstract is intended as a scanning tool for purposes of searching in the particular art and is not intended to be limiting of the present disclosure.

### CROSS REFERENCE TO RELATED APPLICATIONS

This Application claims the benefit of U.S. Provisional Application No. 63/418,886, filed on Oct. 24, 2022, which is incorporated herein by reference in its entirety.

### STATEMENT REGARDING FEDERALLY SPONSORED RESEARCH

This disclosure was made with U.S. government support under grant numbers DE-FE0032112, DE-FE0031665 and DE-FE0026167, awarded by the Department of Energy, and grant number DMR 1916581, awarded by the National Science Foundation. The U.S. government has certain rights in the disclosure.

### BACKGROUND

The rapid climate deterioration due to CO₂ emission and fossil fuel consumption has manifested the significance of technology developing for hydrogen which is an energy carrier with high energy density for versatile energy conversion with the minimum environmental impact. Solid Oxide Cells (SOCs) are versatile electrochemical devices that can be worked in either Solid Oxide Fuel Cells (SOFCs) mode for the generation of electricity using various fuels or Solid Oxide Electrolysis Cells (SOECs) mode to carry out an electrochemical reaction. For example, SOCs that can be powered by pure H₂ for electricity generation in the SOFC mode and can work reversibly as an electrolyzer for H₂ production in the SOEC mode. In the foregoing example, SOCs are predicted to possess unrivaled highest energy conversion efficiencies among all the competing technologies (Ref. 37). After about 30 years of worldwide intensive development, the state-of-the-art commercial SOCs are largely hydrogen electrodes such as Ni-YSZ and Ni-GDC that provide sufficient electrical conductivity and ionic conductivity and catalytic activity for facilitating electrochemical reactions. The SOC electrochemical reactions for the hydrogen electrode take place on an internal surface of the engineered porous electrode and at the triple-phase boundaries (TPBs), where ionic (YSZ or GDC) and electronic conducting phases (Ni) and gas-phase meet (Ref. 1-2). Requirements for high-performance electrodes are high porosity, high surface area, high-density TPBs, sufficient electrical and ionic conductivity, and high catalytic activity (Refs. 3-9), but at the same time achieving sufficient durability and stability required for field and industrial use.

Research has focused on retaining the electrical conductivity, ionic conductivity and catalytic activity from the well-established Ni/YSZ backbone, but increasing the durability of SOC operation, e.g., via modification of an internal surface of a porous Ni/YSZ electrode. Liquid solution-based infiltration is conceptually one approach to modification of an internal surface of Ni/YSZ electrodes. However, for surface modification to be effective, the liquid solution cannot penetrate through a current collecting layer and deliver infiltrated materials into an active layer next to the electrolyte. Depending on fabrication methods, commercial fuel electrode support cells usually have dense fuel electrodes. For example, fuel electrode support button cells fabricated could possess an entire anode thickness of over about 0.3 mm and porosity of ~35%. Accordingly, a concern relating to use of liquid solution infiltration is penetration into the active layer of a fuel electrode of commercial cells.

Moreover, a liquid solution may result in an uncontrolled microstructure of infiltrated materials and may randomly distribute particles with large agglomerations. It has been reported that liquid solution infiltration of Ni, Co, and Fe nano-catalysts into an Ni/YSZ electrode can result in discrete particles contacting the Ni surface where they may alloy with a Ni grain, quickly lose nano-grain features, and degraded catalytic activity (Ref. 36). A further complication is that when discrete Ni, Co, and Fe nano-catalysts contact the YSZ surface they are not activated for electrochemical reactions due to a lack of electrical conducting pathways on the pure ionic conducting YSZ substrate. Thus, liquid infiltration methods as an approach to improve Ni/YSZ electrode durability are limited by at least the foregoing. Additional approaches for modification of an internal surface of a porous Ni/YSZ electrode include a Ni-free all ceramic electrode or in situ exsolution treatment. Unfortunately, these approaches are extremely limited in real world application, e.g., in situ exsolution treatment can only be used with a very narrow type of oxide ceramics.

Thus, despite the critical need for high-performance electrodes for use in SOC applications, currently available solutions are inadequate in several respects, in particular, they do not provide for suitable durability as will be required in widespread use and adoption in meeting green energy goals. These needs and other needs are satisfied by the present disclosure.

### SUMMARY

In accordance with the purpose(s) of the disclosure, as embodied and broadly described herein, the disclosure, in one aspect, relates to ALD-coated electrodes comprising a conformal MnOₓ layer, and optionally, a Pt layer subjacent to the MnOₓ layer. In a further aspect, the ALD-coated electrode is an anode, e.g., a Ni/YSZ electrode. In a still further aspect, the present disclosure relates to cells comprising the disclosed ALD-coated electrodes. In a yet further aspect, the present disclosure relates to devices comprising the disclosed cells. Cells comprising the disclosed electrodes have improved stability and peak power performance.

Disclosed herein are coated electrodes comprising: an electrode comprising a nano-coating; wherein the nano-coating comprises a first coating layer; wherein the first coating layer comprises a continuous conformal layer comprising MnOₓ; wherein the first coating layer penetrates the electrode.

Also disclosed herein are coated electrodes comprising: an electrode comprising a nano-composite coating; wherein the nanocomposite coating comprises a first coating layer; wherein the first coating layer comprises a continuous conformal layer comprising MnOₓ; wherein the first coating layer penetrates the electrode; and a second coating layer subjacent to the first coating layer; wherein the second coating layer comprises Pt.

Also disclosed herein are anodes comprising an atomic deposition layer of single phase YSZ comprising a top surface and a bottom surface wherein the layer of single phase YSZ is doped with manganese atoms wherein the ratio of manganese to zirconium atoms increases from the bottom surface to the top surface.

Also disclosed herein are anodes comprising an atomic deposition layer of YSZ comprising a top surface wherein an atomic deposition layer of platinum nanocuboids overlies the top surface.

Also disclosed herein are cells, i.e., an electrochemical cell, comprising a disclosed coated electrode or disclosed coated anode.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described aspects are usable in all aspects of the disclosure taught herein. Furthermore, the individual features of the dependent claims, as well as all optional and preferred features and modifications of the described aspects are combinable and interchangeable with one another.

### BRIEF DESCRIPTION OF THE FIGURES

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIGS. 1A-1B show representative TEM images pertaining to a disclosed ALD coating of MnOₓ layer on an electrode. FIG. 1A shows an ALD MnOₓ coating on the internal surface of a porous electrode. FIG. 1B shows the ALD MnOₓ coating on the internal surface of a porous electrode of FIG. 1A at great magnification.

FIG. 2 shows representative performance data, i.e., V-i and P-i plots, of a conventional LSM/YSZ cell compared to disclosed LSM/YSZ cells comprising a coated anode. “Baseline” refers to an LSM cell comprising an uncoated anode, and “Anode w Mn” indicates an LSM cell comprising an anode comprising a disclosed MnOₓ coating deposited using ALD methods per the disclosure herein. Baseline cell and the cell with Mn on the anode backbone at various times. The cell labeled “Anode w Mn” was tested at the times indicated in the figure.

FIG. 3 shows representative terminal voltage data of a disclosed LSM cell comprising an anode comprising a disclosed MnOₓ coating deposited using ALD methods per the disclosure herein. The terminal voltage data were collected as a function of time at a constant current density of 0.3 A cm⁻².

FIGS. 4A-4B show representative data plots pertaining to the performance of a disclosed LSM cell comprising an anode comprising a disclosed MnOₓ coating deposited using ALD methods per the disclosure herein compared to a conventional LSM cell. FIG. 4A shows a Nyquist plot based on impedance data collected for a disclosed LSM cell comprising an anode comprising a disclosed MnOₓ coating deposited using ALD methods (labeled in the figure as “AN w Mn” for the indicated times) compared to a conventional LSM cell, i.e., an LSM cell comprising an uncoated anode. FIG. 4B shows a Bode plot based on impedance data collected for a disclosed LSM cell having an anode comprising a disclosed MnOₓ coating deposited using ALD methods (labeled in the figure as “AN w Mn” for the indicated times) compared to a conventional LSM cell, i.e., an LSM cell comprising an uncoated anode.

FIG. 5 shows a schematic representation of a disclosed Pt—Mn nanocomposite coating structure deposited using ALD methods as disclosed herein. Schematically, the Pt—Mn nanocomposite comprises a coating of Pt nanoparticles on the Ni/YSZ electrode surface beneath a MnOₓ coating layer beneath an outer layer of Pt nanoparticles.

FIG. 6 shows representative performance data shows representative performance data, i.e., V-i and P-i plots, of a conventional LSM/YSZ cell (labeled “Baseline” in the figure) compared to disclosed LSM/YSZ cells comprising a coated anode, i.e., a cell comprising an anode having a MnOₓ coating (labeled in the figure as “Anode with Mn”) and a cell comprising a Pt—Mn nanocomposite coating (as described herein and shown schematically in FIG. 5; labeled in the figure as “Anode with Mn+Pt”).

FIG. 7 shows representative terminal voltage data of a disclosed LSM cell comprising an anode comprising Pt—Mn nanocomposite coating (as described herein and shown schematically in FIG. 5) as a function of time at a constant current density of 0.3 A cm⁻².

FIGS. 8A-8C show representative TEM micrographs of a disclosed coated electrode, i.e., a Ni/YSZ electrode comprising a Pt—Mn nanocomposite coating (as described herein and shown schematically in FIG. 5). Scalar bars are shown in each panel. FIG. 8A shows a representative TEM image show Pt nanoparticles as discrete grains on a Mn-enriched YSZ surface. In the figure the Pt discrete grains are present on the YSZ surface, but not on the Ni surface are seen. FIG. 8B shows a similar image at a similar magnification as shown in FIG. 8A with diffraction patterns for the indicated regions, i.e., a region comprising MnOₓ penetrating into the YSZ surface and a region below the region penetrated by MnOₓ. In the figure, the YSZ grain surface possesses a cubic structure, as shown in the diffraction pattern, and the YSZ grain matrix possesses a mixture of cubic and tetragonal, as demonstrated in the diffraction pattern are seen. FIG. 8C shows a section of the YSZ surface at increased magnification with diffraction patterns for the indicated regions. In the figure, the Pt discrete grains and the Mn-enriched YSZ surface with cubic structure are seen.

Additional advantages of the disclosure will be set forth in part in the description which follows, and in part will be obvious from the description, or can be learned by practice of the disclosure. The advantages of the disclosure will be realized and attained by means of the elements and combinations particularly pointed out in the appended claims. It is to be understood that both the foregoing general description and the following detailed description are exemplary and explanatory only and are not restrictive of the disclosure, as claimed.

### DETAILED DESCRIPTION

Many modifications and other aspects disclosed herein will come to mind to one skilled in the art to which the disclosed compositions and methods pertain having the benefit of the teachings presented in the foregoing descriptions and the associated drawings. Therefore, it is to be understood that the disclosures are not to be limited to the specific aspects disclosed and that modifications and other aspects are intended to be included within the scope of the appended claims. The skilled artisan will recognize many variants and adaptations of the aspects described herein. These variants and adaptations are intended to be included in the teachings of this disclosure and to be encompassed by the claims herein.

Although specific terms are employed herein, they are used in a generic and descriptive sense only and not for purposes of limitation.

As will be apparent to those of skill in the art upon reading this disclosure, each of the individual aspects described and illustrated herein has discrete components and features which may be readily separated from or combined with the features of any of the other several aspects without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present disclosure is not entitled to antedate such publication by virtue of prior disclosure. Further, the dates of publication provided herein can be different from the actual publication dates, which can require independent confirmation.

While aspects of the present disclosure can be described and claimed in a particular statutory class, such as the system statutory class, this is for convenience only and one of skill in the art will understand that each aspect of the present disclosure can be described and claimed in any statutory class.

It is also to be understood that the terminology used herein is for the purpose of describing particular aspects only and is not intended to be limiting. Unless defined otherwise, all technical and scientific terms used herein have the same meaning as commonly understood by one of ordinary skill in the art to which the disclosed compositions and methods belong. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

Prior to describing the various aspects of the present disclosure, the following definitions are provided and should be used unless otherwise indicated. Additional terms may be defined elsewhere in the present disclosure.

### A. Definitions

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by”, “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.

As used in the specification and the appended claims, the singular forms “a,” “an” and “the” include plural referents unless the context clearly dictates otherwise. Thus, for example, reference to “an ALD-coated cell,” “a nanocomposite,” or “a nanoparticle,” includes, but is not limited to, two or more such ALD-coated cells, nanocomposites, or nanoparticles, and the like.

As used herein, the term “and/or” includes any and all combinations of one or more of the associated listed items. Expressions such as “at least one of,” when preceding a list of elements, modify the entire list of elements and do not modify the individual elements of the list.

As used herein, nomenclature for compounds, including organic compounds, can be given using common names, IUPAC, IUBMB, or CAS recommendations for nomenclature. When one or more stereochemical features are present, Cahn-Ingold-Prelog rules for stereochemistry can be employed to designate stereochemical priority, E/Z specification, and the like. One of skill in the art can readily ascertain the structure of a compound if given a name, either by systemic reduction of the compound structure using naming conventions, or by commercially available software, such as CHEMDRAW™ (Cambridgesoft Corporation, U.S.A.).

Reference to “a” chemical compound refers to one or more molecules of the chemical compound rather than being limited to a single molecule of the chemical compound. Furthermore, the one or more molecules may or may not be identical, so long as they fall under the category of the chemical compound. Thus, for example, “a” chemical compound is interpreted to include one or more molecules of the chemical, where the molecules may or may not be identical (e.g., different isotopic ratios, enantiomers, and the like).

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less' and should be interpreted to include the specific ranges of ‘about x’, ‘about y’, and ‘about z’ as well as the ranges of ‘less than x’, less than y’, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y’, and ‘greater than z’. In addition, the phrase “about ‘x’ to ‘y’”, where ‘x’ and ‘y’ are numerical values, includes “about ‘x’ to about ‘y’”.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

As used herein, the term “effective amount” refers to an amount that is sufficient to achieve the desired modification of a physical property of the composition or material. For example, an “effective amount” of a nanocomposite layer refers to a nanocomposite layer that is sufficiently thick to achieve the desired improvement in the property modulated by the nanocomposite layer, e.g., conductivity and/or stability of the cell. The specific level in terms of thickness (nm) required as an effective amount will depend upon a variety of factors composition of the cathode, temperature parameters for use, and the like.

As used herein, “solid oxide cell” or “SOC” refers to an electrochemical device that can be operated in SOFC mode for the generation of electricity using various fuels, e.g., hydrogen, or in SOEC mode for storing electricity as a chemical fuel, e.g., converting electricity to fuels such as hydrogen, methane, and methanol. SOCs are one method for the production of green hydrogen using electricity.

As used herein, “solid oxide fuel cell” or “SOFC” refers to an electrochemical conversion device that produces electricity by oxidizing a fuel. Generally speaking, an SOFC generally comprises a solid electrolyte layer with an oxidizer electrode (cathode) on one side of the electrolyte and a fuel electrode (anode) on the other side. Its operation is as follows: reduction of oxygen molecules into oxygen ions occurs at a cathode; an electrolyte material conducts the negative oxygen ions from the cathode to an anode, where electrochemical oxidation of oxygen ions with hydrogen or carbon monoxide occurs; the electrons then flow through an external circuit and re-enter the cathode. The electrodes should be porous, or at least permeable to the oxidizer at the cathode and the fuel at the anode, while the electrolyte layer should be dense so as to prevent leakage of gas across the layer.

As used herein, “solid oxide electrolysis cell” or “SOEC” refers to an electrochemical device that utilizes electricity for electrolysis to carry out an electrochemical reaction, the electrochemical device comprising a solid oxide electrolyte, a fuel-side electrode disposed on a fuel side of the electrolyte, and an air-side electrode disposed on an air side of the electrolyte. In a particular example, an SOEC can comprises a hydrogen electrode, an oxygen electrode, and an electrolyte layer sandwiched between the hydrogen electrode and the oxygen electrode. Exemplary hydrogen electrodes include Ni and gadolinia-doped ceria (GDC) or Ni and yttria-stabilized zirconia (YSZ).

As used herein, “conformal coating” refers to a coating or layer which matches or follows the topography of the underlying substrate.

As used herein, the terms “optional” or “optionally” means that the subsequently described event or circumstance can or cannot occur, and that the description includes instances where said event or circumstance occurs and instances where it does not.

Unless otherwise specified, temperatures referred to herein are based on atmospheric pressure (i.e., one atmosphere).

The following abbreviations are used herein throughout and can be used interchangeably with the corresponding text phrase.

| Abbreviation | Meaning |
|---|---|
| ALD | Atomic layer deposition |
| EDS | Energy Dispersive X-ray Spectroscopy |
| GDC | Gadoliniu-doped ceria (which can also be referred |
| | to as (Gd, Ce)O₂) |
| HRTEM | High resolution transmission electron microscopy |
| Ni-YSZ | Electrode comprising nickel and YSZ. |
| Ni-GDC | Electrode comprising nickel and GDC. |
| Rₛ | Ohmic resistance |
| Rₚ | Polarization resistance |
| SOC | Solid oxide cell |
| SOEC | Solid oxide electrolysis cell |
| SOFC | Solid oxide fuel cell |
| YSZ | Yttria-stabilized zirconia (YSZ) electrolyte (which |
| | can also be referred to as Y₂O₃-stabilized ZrO2 |
| | or yttria-stabilized zirconia) |
| TEM | Transmission electron microscopy |
| TPB | Triple phase boundary |

### B. Introduction

In one aspect, the disclosure relates to methods and devices to address the critical need for high-performance electrodes for use in SOC applications. In particular, present disclosure relates to methods and devices for coated electrodes, such as anodes, including Ni/YSZ electrodes comprising a conformal MnOₓ coating provided by ALD methods, and optionally, a coating comprising Pt. The disclosed electrodes have enhanced durability and performance compared to conventionally available electrodes, including current state of the art Ni/YSZ electrodes. The disclosed electrodes provide an advancement to SOC cells, including both SOEC and SOFC cells, that should help in meeting green energy goals.

In a further aspect, an advantage of the disclosed methods of providing a coating to an electrode surface is that these methods can be utilized with ready-for-use, manufactured cells comprising a cathode, an anode, and an electrolyte. That is, the methods are inexpensive and useful with SOC cells that are currently manufactured and do not require a change in the manufacturing workflow currently producing SOC cells. The disclosed methods can be readily utilized with SOC cells as a post-production step to provide the disclosed coatings to an electrode, such as an anode, surface for improved durability and performance.

### C. ALD-Coated Electrodes

In one aspect, the disclosure relates to the ALD coating of Mn of Ni/YSZ fuel electrode has resulted in over 30% reduction of the series resistance of the entire cell. Such reduction of resistance and increased conductivity is accompanied by nano-structure changes induced by ALD coating (1) doping the YSZ and introducing the electronic conductivity (2). On the surface of the YSZ grains, the Mn doping has also changed the YSZ structure from a mixture of tetragonal and cubic to a cubic structure that possesses higher ionic conductivity than that of the mixture of cubic tetragonal structures. Upon ALD coating of nano-composite and MnOₓ and Pt, there is the spontaneous formation of the uniform discrete nano-Pt on the YSZ surface. The synergistic interactions of the increased ionic conductivity, the additional electrical conductivity, as well as the spontaneously pinned Pt nano-Pt show that the peak power increased by up to 57%. For the anode-supported commercial cells, the cell performance is deemed as dominated by the cathode performance. The large cell power density increase to 57% is the first report achieved by the ALD coating of the Ni/YSZ anode of commercial cells. While keeping the Pt loading to be minimum, it is expected that the performance could be further improved by adjusting the MnOₓ layer thickness. Most importantly, our work here demonstrates that electrical conductivity could be induced on ionic conducting YSZ, and both the conductivity and the ALD coating of the nano-catalysts could be spontaneously pinned on the YSZ surface to increase the electrochemical reaction sites. The ALD coating provides an effective and versatile approach to increase both the catalytic activity and the conductivity.

In a further aspect, the coated electrodes comprise a coating provided by Atomic Layer Deposition (ALD). In a still further aspect, the coating comprises a first coating layer comprising a transition metal, e.g., Mn in the form of MnOₓ. In a further aspect, the first coating layer is a continuous conformal layer and penetrates the electrode. Optionally, the coating can comprise a second coating layer subjacent to the first coating layer. In some instances, the electrode which is coated is a Ni/YSZ electrode.

The first coating layer can have a thickness of from about 1 nm to about 200 nm, about 2 nm to about 40 nm, about 2 nm to about 20 nm, about 5 nm to about 20 nm, about 10 nm to about 20 nm, about 5 nm to about 15 nm, or about 20 nm. In another aspect, the first coating layer can penetrate the surface of the electrode to a depth of from about 1 nm to about 30 nm, about 1 nm to about 20 nm, about 1 nm to about 15 nm, about 1 nm to about 10 nm, about 1 nm to about 5 nm, about 5 nm to about 20 nm, about 5 nm to about 15 nm, about 5 nm to about 10 nm, or about 10 nm.

In another aspect, when the coated electrode is a Ni/YSZ electrode, the first coating layer can penetrate the surface of the electrode to a depth of from about 1 nm or about 30 nm, about 1 nm to about 15 nm, about 5 nm to about 20 nm, about 5 nm to about 10 nm, or about 10 nm. In a further aspect, within the depth of penetration there is a penetrated ratio of Mn:Zr. The Mn:Zr penetrated ratio which can be from about 0.1 to about 0.5, about 0.1 to about 0.4, about 0.15 to about 0.5, about 0.15 to about 0.4, about 0.2 to about 0.5, about 0.2 to about 0.4, about 0.3 to about 0.4, or about 0.37. In another aspect, beneath the depth of penetration of the first coating layer, the Ni/YSZ electrode has a doping ratio of Mn:Zr. The Mn:Zr doping ratio can be less than or equal to about 0.15, less than or equal to about 0.12, less than or equal to about 0.10, or less than or equal to about 0.08.

In another aspect, when the first coating layer penetrates the surface of the electrode (such as the Ni/YSZ electrode), the depth penetrated by the first layer can include YSZ and MnOₓ. In a further aspect, this depth penetrated by the first coating layer can have an altered crystal structure compared to untreated YSZ that lacks a first coating layer. In yet a further aspect, the depth penetrated by the first coating layer can comprise a cubic crystal structure, while the crystal structure of the untreated YSZ that lacks a first coating layer can be a mixture of cubic and tetragonal.

The coated electrode can, in some aspects, further include a second coating layer, where the second coating layer is subjacent to the first coating layer and includes Pt. Prior to the coated electrode being operated in a cell that includes the coated electrode, the thickness of the second coating layer can be from about 0.5 nm to about 10 nm, about 0.5 nm to about 7 nm, about 0.5 nm to about 5 nm, about 0.5 nm to about 4 nm, about 0.5 nm to about 3 nm, about 1 nm to about 7 nm, about 1 nm to about 5 nm, about 1 nm to about 4 nm, or about 1 nm to about 3 nm. In a further aspect, the coated electrode can include discrete nanoparticles of Pt superjacent to the first coating layer after the coated electrode is operated in a cell at about 300° C. to about 1200° C., about 500° C. to about 1000° C., about 600° C. to about 900° C., about 700° C. to about 800° C., about 720° C. to about 780° C., or about 750° C. The discrete Pt nanoparticles can be about 1 nm to about 10 nm, about 1 nm to about 7 nm, about 1 nm to about 5 nm, about 2 nm to about 10 nm, about 2 nm to about 7 nm, about 2 nm to about 5 nm, or about 3 nm in the longest dimension. In a further aspect, the discrete Pt nanoparticles can have a cuboid geometry.

In another aspect, a coated cell including the coated electrode (in some aspects, as an anode), can have an increase in peak power of at least about 5%, at least about 10%, at least about 20%, at least about 30%, at least about 50%, at least about 100%, at least about 200%, or at least about 300% compared to a conventional cell, where the conventional cell is identical to the coated cell except that is comprises an anode without the first coating layer or without including the first coating layer and second coating layer. In a further aspect, the coated cell can have an increase in peak power of from about 5% to about 1000%, from about 10% to about 900%, from about 20% to about 800%, from about 50% to about 700%, or from about 30% to about 100% compared to a conventional cell.

In another aspect, a coated cell comprising any one of the coated electrodes disclosed herein (in some aspects, as an anode) can have a terminal voltage that changes by less than or equal to about 10%, less than or equal to about 7%, less than or equal to about 5%, less than or equal to about 3%, or less than or equal to about 1% when comparing the initial terminal voltage to a terminal voltage of at least 100 h of operation at a constant current density of about or equal to 0.3 A cm⁻².

In another aspect, the disclosed coated electrodes are stable for extended times at high temperatures. In a further aspect, the disclosed coated electrodes comprise a coating that is deposited by ALD methods as discussed herein, and the ALD-deposited coating is associated with increased thermal stability of the electrode itself, thus allowing for their use in high-temperature electrochemical applications on SOCs.

In a further aspect, the ALD-deposited coatings are coatings on an electrode such as a Ni/YSZ electrode. In a still further aspect, the disclosed coatings include conformal MnOₓ coatings and/or a nanocomposite of MnOₓ and/or a nano-Pt. In another aspect, an electrode (in some aspects, an anode) has an ALD-deposited coating of single-phase YSZ doped with manganese atoms and including a top surface and a bottom surface. This electrode has a ratio of manganese to zirconium atoms that increases from the bottom surface to the top surface. In some aspects, this ratio increases from about 0.05 to about 0.4, about 0.08 to about 0.375, about 0.1 to about 0.4, or about 0.1 to about 0.375. In a further aspect, the single phase YSZ of the electrode is a simple cubic phase. In another aspect, the electrode can further include platinum atoms pinned to the top surface.

In another aspect, an anode including an ALD-deposited layer of YSZ with a top surface can further include an ALD-deposited layer of platinum nanocuboids which overlies the top surface.

In another aspect, an electrochemical cell can include any one of the electrodes or anodes disclosed herein. The electrochemical cell can further include an LSM/YSZ cathode. In a further aspect, the electrochemical cell has a peak power that increases by from about 30% to about 100%, about 50% to about 300%, or about 100% to about 200% compared to a baseline electrode or anode that is not coated.

In a further aspect, when the disclosed coated electrodes comprising a disclosed Pt—Mn nanocomposite are used in an electrochemical operation at a high temperature of 750° C., spontaneously growing, self-assembled nanoparticles of Pt form that comprise stable uniform discrete nano cuboids. These nanocuboids grow and are pinned on an internal surface of a YSZ surface superjacent to the MnOₓ coating and initial Pt ALD-coating subjacent to the MnOₓ coating. The self-assembled nanoparticles of Pt provide a catalytic surface superjacent to the MnOₓ coating and underlying Ni/YSZ electrode.

In a further aspect, when the disclosed coated electrodes comprising a disclosed MnOₓ coating or a Pt—Mn nanocomposite coating are used in electrochemical operation, the MnOₓ increases the conductivity of the cell.

### D. Methods of Preparing the Disclosed ALD-Coated Electrodes

In one aspect, the disclosure relates to a method of forming a multi-layer electrocatalyst nanostructure on an electrode using atomic layer deposition (ALD). In a further aspect, the disclosed method includes using ALD to deposit a first layer comprising a continuous conformal layer comprising MnOₓ. In a still further aspect, the disclosed method includes using ALD to deposit a second layer comprising Pt subjacent to the first layer comprising a continuous conformal layer comprising MnOₓ.

ALD is a chemical vapor deposition technique that sequentially applies atomic monolayers to a substrate, typically alternating compounds to produce a locally balanced atomic distribution of the target material. ALD is very suited for depositing uniform and conformal films on complex three-dimensional topographies with a high aspect ratio. In a further aspect, the disclosed methods using ALD to provide a coating, e.g., a conformal MnOₓ coating or a Pt—Mn nanocomposite coating to an as-fabricated, inherently functional SOC. That is, the disclosed methods allow post-processing addition of a coating to an electrode surface, e.g., an anode, in an already fabricated and functional SOC. The indifference of ALD coating to substrate shape and substrate crystal orientation is advantageous for coating and designing conformal layers to an internal surface of an electrode, such as an electrode comprising a porous active structure with complex three-dimensional topographies, wherein electrode performance may depend on these and other structural properties.

Generally speaking, atomic layer deposition is a subclass of chemical vapor deposition and encompasses a thin-film deposition technique based on the sequential use of a gas phase chemical process. During atomic layer deposition a film is grown on a substrate by exposing its surface to alternate gaseous species, typically referred to as precursors. The precursor molecules react with the surface in a self-limiting way, so that the reaction terminates once all the reactive sites on the surface are consumed. Consequently, the maximum amount of material deposited on the surface after a single exposure to all of the precursors (a so-called ALD cycle) is determined by the nature of the precursor-surface interaction. By varying the number of cycles it is possible to grow materials uniformly and with high precision on arbitrarily complex and large substrates. Through the repeated exposure to separate precursors, a thin film is slowly deposited on a target surface. The chemistry of any particular layer can be specified or modified by selecting the precursors, the oxidant, the processing temperature, the processing pressure, or a combination thereof, each of which can be automated and controlled with a control system. ALD is considered one deposition method with great potential for producing very thin, conformal films with control of the thickness and composition of the films possible at the atomic level.

According to various aspects, the ALD technique comprises introducing a precursor and an oxidant to the subjacent layer or surface and allowing the precursor to react with the subjacent layer or surface, forming a thin film layer thereon. The precursor can be selected from any suitable precursor that will provide the desired layer by ALD. Exemplary Pt precursors include, for example: platinum metal, platinum(II) acetylacetonate; platinum(II) hexafluoroacetylacetonate; (trimethyl)cyclopentadienylplatinum(IV); (trimethyl)methylcyclopentadienylplatinum(IV). Exemplary Mn precursors include, for example: a cyclopentadienyl-based manganese compound, an amidinate-based manganese compound and/or an amide amino alkane-based manganese compound, including, but not limited to, a bis(alkylcyclopentadienyl) manganese expressed by a general formula Mn(RC₅H₄)₂ such as Cp₂Mn[═Mn(C₅H₅)₂], (MeCp)₂Mn[═Mn(CH₃C₅H₄)₂], (EtCp)₂Mn[═Mn(C₂H₅C₅H₄)₂], (i-PrCp)₂Mn[═Mn(C₃H₇C₅H₄)₂] and (t-BuCp)₂Mn[═Mn(C₄H₉C₅H₄)₂]. In a further aspect, the Mn precursor can be a compound such as bis(ethylcyclopentadienyl)manganese. In a yet further aspect, the amidinate-based manganese compound, a bis(N,N′-dialkylacetamidinate) manganese expressed as a general formula of Mn(R¹N—CR³—NR²)₂ disclosed in U.S. Publication No. US2009/0263965A1 may be used. In a still further aspect, the amideaminoalkane-based manganese compound, a bis(N,N′-1-alkylamide-2-dialkylaminoalkane) manganese expressed as a general formula of Mn(R′N—Z—NR²²)₂ disclosed in International Publication No. WO2012/060428 may be used. Here, in the above general formulas, “R, R¹, R², and R³” are functional groups described as —CₙH₂ₙ₊₁ (n is an integer of 0 or more), and “Z” is a functional group described as —CₙH₂ₙ— (n is an integer of 1 or more). Alternatively, as other manganese compounds, a carbonyl-based manganese compound and a beta-diketone-based manganese compound may be used. As the carbonyl-based manganese compound, decacarbonyl 2 manganese (Mn₂(CO)₁₀) or methylcyclopentadienyl manganese tricarbonyl ((CH₃C₅H₄)Mn(CO)₃) may be used. The oxidant can be selected from any suitable oxidant that will provide the desired electrocatalyst layer. Exemplary oxidants include hydrogen peroxide (H₂O₂), water (H₂O), oxygen (O₂) and ozone (O₃). As an alternative to the foregoing oxidants, an oxygen containing material can be used such as N₂O, NO₂, NO, CO, CO₂, or alcohols, such as methyl alcohol or ethyl alcohol.

### E. References

References are cited herein throughout using the format of reference number(s) enclosed by parentheses corresponding to one or more of the following numbered references. For example, citation of references numbers 1 and 2 immediately herein below would be indicated in the disclosure as (Refs. 1 and 2).
[Ref. 1] Adler, S. B. Chemical Reviews 2004, 104, 4791-4843.
[Ref. 2] Sholklapper T Z, Radmilovic V, Jacobson C P, Visco S J, De Jonghe L C. Nanocomposite Ag-LSM solid oxide fuel cell electrodes. Journal of Power Sources. 2008; 175(1):206-10.
[Ref. 3] Chen K, Ai N. Performance and structural stability of Gd0.2Ce0.8O1.9 infiltrated La0.8Sr0.2MnO3 nano-structured oxygen electrodes of solid oxide electrolysis cells. International journal of hydrogen energy. 2014; 39(20):10349-58.
[Ref. 4] Mogoteguy P, Brisse A. A review and comprehensive analysis of degradation mechanisms of solid oxide electrolysis cells. International journal of hydrogen energy. 2013; 38(36):15887-902.
[Ref. 5] Ding D, Li X, Lai S Y, Gerdes K, Liu M. Enhancing SOFC cathode performance by surface modification through infiltration. Energy & Environmental Science. 2014; 7(2):552-75.
[Ref. 6] Vohs J M, Gorte R J. High-Performance SOFC Cathodes Prepared by Infiltration. Advanced Materials. 2009; 21(9):943-56.
[Ref. 7] Shah M, Voorhees P W, Barnett S A. Time-dependent performance changes in LSCF-infiltrated SOFC cathodes: The role of nano-particle coarsening. Solid State lonics. 2011; 187(1):64-7.
[Ref. 8] Knofel C, Wang H J, Thyden K T S, Mogensen M. Modifications of interface chemistry of LSM-YSZ composite by ceria nanoparticles. Solid State lonics. 2011; 195(1):36-42.
[Ref. 9] Song X, Lee S, Chen Y, Gerdes K. Electrochemically influenced cation inter-diffusion and Co3O4 formation on La0.6Sr0.4CoO3 infiltrated into SOFC cathodes. Solid State lonics. 2015; 278:91-7.
[Ref. 10] Lee, K. T.; Wachsman, E. D., Role of nanostructures on SOFC performance at reduced temperatures. Mrs Bull 2014, 39 (9), 783-791.
[Ref. 11] Anthony S. Yu, Rainer Kungas, John M. Vohs, and Raymond J. Gorte, Modification of SOFC Cathodes by Atomic Layer Deposition, Journal of The Electrochemical Society, 160 (11) F1225-F1231 (2013).
[Ref. 12] Theodore E. Burye, Jason D. Nicholas. “Improving La0.6Sr0.4Co0.8Fe0.2O3 Infiltrated Solid Oxide Fuel Cell Cathode Performance through Precursor Solution Desiccation,” Journal of Power Sources, v.276, (2015), p. 54
[Ref. 13] Wang, H., Yakal-Kremski, K. J., Yeh, T., Rupp, G. M., Limbeck, A., Fleig, J. & Barnett, S. A. “Mechanisms of Performance Degradation of (La,Sr)(Co,Fe)O3 Solid Oxide Fuel Cell Cathodes.,” Journal of The Electrochemical Society, v.163, 2016, p. F581.
[Ref. 14] Onn T, Kungas R, Fornasiero P, Huang K, Gorte R. Atomic layer deposition on porous materials: Problems with conventional approaches to catalyst and fuel cell electrode preparation. Inorganics. 2018; 6(1):34.
[Ref. 15] Chao C C, Park J S, Tian X, Shim J H, Gur™, Prinz F B. Enhanced Oxygen Exchange on Surface Engineered Yttria-Stabilized Zirconia. Acs Nano. 2013; 7(3):2186-91.
[Ref. 16] Miikkulainen V, Leskela M, Ritala M, Puurunen R L. Crystallinity of inorganic films grown by atomic layer deposition: Overview and general trends. Journal of Applied Physics. 2013; 113(2) 021301.
[Ref. 17] Maier, J., Thermodynamics of Nano Systems with a Special View to Charge Carriers. Advanced Materials 2009, 21 (25-26), 2571-2585.
[Ref. 18] Chadwick, A. V., Transport in defective ionic materials: from bulk to nanocrystals. physica status solidi (a) 2007, 204 (3), 631-641.
[Ref. 19] Chen, Song, Yun Chen, Harry Finklea, Xueyan Song, Gregory Hackett and Kirk Gerdes. “Crystal Defects of Yttria Stabilized Zirconia in Solid Oxide Fuel Cells and Their Evolution Upon Cell Operation.” Solid State lonics 206, no. 0 (2012): 104-111.
[Ref. 20] Chen S, Chen Y, Finklea H, Song X, Hackett G, Gerdes K. Crystal defects of yttria stabilized zirconia in Solid Oxide Fuel Cells and their evolution upon cell operation. Solid State lonics. 2012; 206(0):104-11.
[Ref. 21] https://en.wikipedia.org/wiki/Electrical_resistivity_and_conductivity
[Ref. 22] Chen, Yun, Kirk Gerdes, Sergio Paredes Navia, Liang Liang, Alec Hinerman and Xueyan Song. “Conformal Electrocatalytic Surface Nanoionics for Accelerating High-Temperature Electrochemical Reactions in Solid Oxide Fuel Cells.” Nano letters, (2019).
[Ref. 23] George, S. M. Atomic layer deposition: an overview. Chemical Reviews 2010, 110, 111-131.
[Ref. 24] Miikkulainen, V.; Leskela, M.; Ritala, M.; Puurunen, R. L. Crystallinity of inorganic films grown by atomic layer deposition: Overview and general trends. Journal of Applied Physics 2013, 113, 021301.
[Ref. 25] Chao, C.-C.; Motoyama, M.; Prinz, F. B. Nanostructured Platinum Catalysts by Atomic-Layer Deposition for Solid-Oxide Fuel Cells. Adv. Energy Mater. 2012, 2 (6), 651-654.
[Ref. 26] Jiang, X.; Gur, T. M.; Prinz, F. B.; Bent, S. F. Atomic layer deposition (ALD) Co-deposited Pt—Ru binary and Pt skin catalysts for concentrated methanol oxidation. Chemistry of Materials 2010, 22, 3024-3032.
[Ref. 27]O'Neill, B. J.; Jackson, D. H.; Lee, J.; Canlas, C.; Stair, P. C.; Marshall, C. L.; Elam, J. W.; Kuech, T. F.; Dumesic, J. A.; Huber, G. W. Catalyst design with atomic layer deposition. ACS Catalysis 2015, 5, 1804-1825.
[Ref. 28] Choi, H. J.; Bae, K.; Grieshammer, S.; Han, G. D.; Park, S. W.; Kim, J. W.; Jang, D. Y.; Koo, J.; Son, J. W.; Martin, M. Surface Tuning of Solid Oxide Fuel Cell Cathode by Atomic Layer Deposition. Adv. Energy Mater. 2018, 8 (33), 1802506.
[Ref. 29] Chen, Y.; Gerdes, K.; Song, X. Nanoionics and Nanocatalysts: Conformal Mesoporous Surface Scaffold for Cathode of Solid Oxide Fuel Cells. Sci Rep 2016, 6, 32997.
[Ref. 30] Debe, M. K. Electrocatalyst approaches and challenges for automotive fuel cells. Nature. 2012; 486(7401):43.
[Ref. 31] Chen, Yun, Kirk Gerdes and Xueyan Song. “Nanoionics and Nanocatalysts: Conformal Mesoporous Surface Scaffold for Cathode of Solid Oxide Fuel Cells.” Scientific Reports 6, (2016): 32997.
[Ref. 32] Shin, S. M.; Yoon, B. Y.; Kim, J. H.; Bae, J. M. Performance improvement by metal deposition at the cathode active site in solid oxide fuel cells. International Journal of Hydrogen Energy 2013, 38(21), 8954-8964.
[Ref. 33] Xiong, Y.; Yamaji, K.; Kishimoto, H.; Brito, M. E.; Horita, T.; Yokokawa, H. Deposition of Platinum Particles at LSM/ScSZ/Air Three-Phase Boundaries Using a Platinum Current Collector. Electrochem. Solid State Lett. 2009, 12(3), B31-B33.
[Ref. 34] Neagu D, Oh T-S, Miller D N, Menard H, Bukhari S M, Gamble S R, et al. Nano-socketed nickel particles with enhanced coking resistance grown in situ by redox exsolution. Nature communications. 2015; 6(1):1-8.
[Ref. 35] Kim K J, Rath M K, Kwak H H, Kim H J, Han J W, Hong S-T, et al. A highly active and redox-stable SrGdNi0.2Mn0.8O4±δ anode with in situ exsolution of nanocatalysts. ACS Catalysis. 2019; 9(2):1172-82.
[Ref. 36] Chen K, Jiang S P. Materials degradation of solid oxide electrolysis cells. Journal of The Electrochemical Society. 2016; 163(11):F3070-F83.

### F. Aspects

The following listing of exemplary aspects supports and is supported by the disclosure provided herein.

Aspect 1. A coated electrode comprising: an electrode comprising a nano-coating; wherein the nano-coating comprises a first coating layer; wherein the first coating layer comprises a continuous conformal layer comprising MnOₓ; wherein the first coating layer penetrates the electrode.

Aspect 2a. The coated electrode of Aspect 1, wherein the first coating layer has a thickness from about 1 nm to about 500 nm.

Aspect 2b. The coated electrode of Aspect 2a, wherein the first coating layer has a thickness from about 1 nm to about 200 nm.

Aspect 3. The coated electrode of Aspect 2a, wherein the first coating layer has a thickness from about 2 nm to about 40 nm.

Aspect 4. The coated electrode of Aspect 2a, wherein the first coating layer has a thickness from about 2 nm to about 20 nm.

Aspect 5. The coated electrode of Aspect 2a, wherein the first coating layer has a thickness from about 5 nm to about 20 nm.

Aspect 6. The coated electrode of Aspect 2a, wherein the first coating layer has a thickness from about 10 nm to about 20 nm.

Aspect 7. The coated electrode of Aspect 2a, wherein the first coating layer has a thickness from about 5 nm to about 15 nm.

Aspect 8. The coated electrode of any one of Aspect 1-Aspect 7, wherein the first coating layer penetrates the surface of the electrode to a depth from about 1 nm to about 30 nm.

Aspect 9. The coated electrode of Aspect 8, wherein the first coating layer penetrates the surface of the electrode to a depth from about 1 nm to about 20 nm.

Aspect 10. The coated electrode of Aspect 8, wherein the first coating layer penetrates the surface of the electrode to a depth from about 1 nm to about 15 nm.

Aspect 11. The coated electrode of Aspect 8, wherein the first coating layer penetrates the surface of the electrode to a depth from about 1 nm to about 10 nm.

Aspect 12. The coated electrode of Aspect 8, wherein the first coating layer penetrates the surface of the electrode to a depth from about 1 nm to about 5 nm.

Aspect 13. The coated electrode of Aspect 8, wherein the first coating layer penetrates the surface of the electrode to a depth from about 5 nm to about 20 nm.

Aspect 14. The coated electrode of Aspect 8, wherein the first coating layer penetrates the surface of the electrode to a depth from about 5 nm to about 15 nm.

Aspect 15. The coated electrode of Aspect 8, wherein the first coating layer penetrates the surface of the electrode to a depth from about 5 nm to about 10 nm.

Aspect 16. The coated electrode of any one of Aspect 1-Aspect 15, wherein the electrode is a Ni/YSZ electrode or a fuel electrode comprising a redox stable oxide.

Aspect 17. The coated electrode of Aspect 16, wherein the first coating layer penetrates the surface of the electrode to a depth from about 1 nm to about 30 nm; and wherein within the depth of penetration there is a penetrated ratio of Mn:Zr of from about 0.1 to about 0.5.

Aspect 18. The coated electrode of Aspect 17, wherein within the depth of penetration there the penetrated ratio of Mn:Zr of from about 0.1 to about 0.4.

Aspect 19. The coated electrode of Aspect 17, wherein within the depth of penetration there the penetrated ratio of Mn:Zr of from about 0.15 to about 0.5.

Aspect 20. The coated electrode of Aspect 17, wherein within the depth of penetration there the penetrated ratio of Mn:Zr of from about 0.15 to about 0.4.

Aspect 21. The coated electrode of Aspect 17, wherein within the depth of penetration there the penetrated ratio of Mn:Zr of from about 0.2 to about 0.5.

Aspect 22. The coated electrode of Aspect 17, wherein within the depth of penetration there the penetrated ratio of Mn:Zr of from about 0.2 to about 0.4.

Aspect 23. The coated electrode of any one of Aspect 17-Aspect 22, wherein beneath the depth of penetration of the first coating layer, the Ni/YSZ has a doping ratio of Mn:Zr less than or equal to about 0.15.

Aspect 24. The coated electrode of Aspect 23, wherein the doping ratio of Mn:Zr less than or equal to about 0.12.

Aspect 25. The coated electrode of Aspect 23, wherein the doping ratio of Mn:Zr less than or equal to about 0.10.

Aspect 26. The coated electrode of Aspect 23, wherein the doping ratio of Mn:Zr less than or equal to about 0.08.

Aspect 27. The coated electrode of any one of Aspect 8-Aspect 26, wherein the first coating layer penetrates surface of the electrode to a depth of about 1 nm to about 30 nm; wherein in the depth penetrated by the first coating layer comprises YSZ or an oxide conductor and MnOₓ; and wherein the depth penetrated by the first coating layer comprises an altered crystal structure compared to untreated YSZ that lacks a first coating layer.

Aspect 28. The coated electrode of Aspect 27, wherein the depth penetrated by the first coating layer comprises a cubic crystal structure.

Aspect 29. The coated electrode of Aspect 27 or Aspect 28, wherein the untreated YSZ that lacks a first coating layer has a cubic/cubic+tetragonal crystal structure.

Aspect 30. The coated electrode of any one of Aspect 1-Aspect 29, wherein the coated electrode further comprises a second coating later; wherein the second coating layer is subjacent to the first coating layer; wherein the second coating layer comprises Pt; and wherein the second coating layer has a thickness of about 0.5 nm to about 10 nm prior to the coated electrode being operated in a cell comprising the coated electrode.

Aspect 31. The coated electrode of Aspect 30, wherein the second coating before has a thickness of about 0.5 nm to about 7 nm prior to the coated electrode being operated in a cell comprising the coated electrode.

Aspect 32. The coated electrode of Aspect 30, wherein the second coating before has a thickness of about 0.5 nm to about 5 nm prior to the coated electrode being operated in a cell comprising the coated electrode.

Aspect 33. The coated electrode of Aspect 30, wherein the second coating before has a thickness of about 0.5 nm to about 4 nm prior to the coated electrode being operated in a cell comprising the coated electrode.

Aspect 34. The coated electrode of Aspect 30, wherein the second coating before has a thickness of about 0.5 nm to about 3 nm prior to the coated electrode being operated in a cell comprising the coated electrode.

Aspect 35. The coated electrode of Aspect 30, wherein the second coating before has a thickness of about 1 nm to about 7 nm prior to the coated electrode being operated in a cell comprising the coated electrode.

Aspect 36. The coated electrode of Aspect 30, wherein the second coating before has a thickness of about 1 nm to about 7 nm prior to the coated electrode being operated in a cell comprising the coated electrode.

Aspect 37. The coated electrode of Aspect 30, wherein the second coating before has a thickness of about 1 nm to about 5 nm prior to the coated electrode being operated in a cell comprising the coated electrode.

Aspect 38. The coated electrode of Aspect 30, wherein the second coating before has a thickness of about 1 nm to about 4 nm prior to the coated electrode being operated in a cell comprising the coated electrode.

Aspect 39. The coated electrode of Aspect 30, wherein the second coating before has a thickness of about 1 nm to about 3 nm prior to the coated electrode being operated in a cell comprising the coated electrode.

Aspect 40. The coated electrode of any one of Aspect 30-Aspect 39, wherein the coated electrode comprises discrete nanoparticles of Pt superjacent to the first coating layer after the coated electrode is operated in a cell at about 300° C. to about 1200° C.; and wherein the discrete Pt nanoparticles are about 1 nm to about 10 nm in the longest dimension.

Aspect 41. The coated electrode of Aspect 40, wherein the coated electrode is operated in a cell at about 500° C. to about 1000° C.

Aspect 42. The coated electrode of Aspect 40, wherein the coated electrode is operated in a cell at about 600° C. to about 900° C.

Aspect 43. The coated electrode of Aspect 40, wherein the coated electrode is operated in a cell at about 700° C. to about 800° C.

Aspect 44. The coated electrode of Aspect 40, wherein the coated electrode is operated in a cell at about 720° C. to about 780° C.

Aspect 45. The coated electrode of Aspect 40, wherein the discrete Pt nanoparticles are about 1 nm to about 10 nm in the longest dimension.

Aspect 46. The coated electrode of Aspect 40, wherein the discrete Pt nanoparticles are about 1 nm to about 7 nm in the longest dimension.

Aspect 47. The coated electrode of Aspect 40, wherein the discrete Pt nanoparticles are about 1 nm to about 5 nm in the longest dimension.

Aspect 48. The coated electrode of Aspect 40, wherein the discrete Pt nanoparticles are about 2 nm to about 10 nm in the longest dimension.

Aspect 49. The coated electrode of Aspect 40, wherein the discrete Pt nanoparticles are about 2 nm to about 7 nm in the longest dimension.

Aspect 50. The coated electrode of Aspect 40, wherein the discrete Pt nanoparticles are about 2 nm to about 5 nm in the longest dimension.

Aspect 51. The coated electrode of any one of Aspect 40-Aspect 50, wherein the discrete Pt nanoparticles have a cuboid geometry.

Aspect 52. The coated electrode of any one of Aspect 1-Aspect 51, wherein a coated cell comprising an anode the coated electrode of the preceding Aspects has an increase in peak power of at least about 5% compared to a conventional cell; and wherein the conventional cell is identical to the coated cell except that it comprises an anode without the first coating layer or comprising the first coating layer and second coating layer.

Aspect 53. The coated electrode of Aspect 52, wherein the coated cell comprising an anode the coated electrode has an increase in the peak power of at least about 10% compared to a conventional cell.

Aspect 54. The coated electrode of Aspect 52, wherein the coated cell comprising an anode the coated electrode has an increase in the peak power of at least about 20% compared to a conventional cell.

Aspect 55. The coated electrode of Aspect 52, wherein the coated cell comprising an anode the coated electrode has an increase in the peak power of at least about 50% compared to a conventional cell.

Aspect 56. The coated electrode of Aspect 52, wherein the coated cell comprising an anode the coated electrode has an increase in the peak power of at least about 100% compared to a conventional cell.

Aspect 57. The coated electrode of Aspect 52, wherein the coated cell comprising an anode the coated electrode has an increase in the peak power of at least about 200% compared to a conventional cell.

Aspect 58. The coated electrode of Aspect 52, wherein the coated cell comprising an anode the coated electrode has an increase in the peak power of at least about 300% compared to a conventional cell.

Aspect 59. The coated electrode of Aspect 52, wherein the coated cell comprising an anode the coated electrode has an increase in the peak power of at from about 5% to about 1000% compared to a conventional cell.

Aspect 60. The coated electrode of Aspect 52, wherein the coated cell comprising an anode the coated electrode has an increase in the peak power of at from about 10% to about 900% compared to a conventional cell.

Aspect 61. The coated electrode of Aspect 52, wherein the coated cell comprising an anode the coated electrode has an increase in the peak power of at from about 20% to about 800% compared to a conventional cell.

Aspect 62. The coated electrode of Aspect 52, wherein the coated cell comprising an anode the coated electrode has an increase in the peak power of at from about 50% to about 700% compared to a conventional cell.

Aspect 63. The coated electrode of any one of Aspect 1-Aspect 62, wherein a coated cell comprising an anode the coated electrode has a terminal voltage changes by less than or equal to about 10% when comparing the initial terminal voltage to a terminal voltage of at least 100 h of operation at a constant current density of 0.3 A cm-2.

Aspect 64. The coated electrode of Aspect 63, wherein the terminal voltage changes by less than or equal to about 7% when comparing the initial terminal voltage to a terminal voltage of at least 100 h of operation at a constant current density of 0.3 A cm⁻².

Aspect 65. The coated electrode of Aspect 63, wherein the terminal voltage changes by less than or equal to about 5% when comparing the initial terminal voltage to a terminal voltage of at least 100 h of operation at a constant current density of 0.3 A cm⁻².

Aspect 66. The coated electrode of Aspect 63, wherein the terminal voltage changes by less than or equal to about 3% when comparing the initial terminal voltage to a terminal voltage of at least 100 h of operation at a constant current density of 0.3 A cm⁻².

Aspect 67. The coated electrode of Aspect 63, wherein the terminal voltage changes by less than or equal to about 1% when comparing the initial terminal voltage to a terminal voltage of at least 100 h of operation at a constant current density of 0.3 A cm⁻².

Aspect 68. An anode comprising an atomic deposition layer of single phase YSZ comprising a top surface and a bottom surface wherein the layer of single phase YSZ is doped with manganese atoms wherein the ratio of manganese to zirconium atoms increases from the bottom surface to the top surface.

Aspect 69. The anode of Aspect 68 wherein the ratio increases from about 0.05 to about 0.4

Aspect 70. The anode of Aspect 68 wherein the ratio increases from about 0.08 to about 0.375.

Aspect 71. The anode of Aspect 68 wherein the single phase is a simple cubic phase.

Aspect 72. The anode of Aspect 68 further comprising platinum atoms pinned to the top surface.

Aspect 73. An anode comprising an atomic deposition layer of YSZ comprising a top surface wherein an atomic deposition layer of platinum nanocuboids overlies the top surface.

Aspect 74. An anode comprising the electrode of any one of Aspect 1-Aspect 67.

Aspect 75. An electrochemical cell comprising the electrode of any one of Aspect 1-Aspect 67 or the anode of any one of Aspect 68-Aspect 74.

Aspect 76. The electrochemical cell of Aspect 75 comprising an LSM/YSZ cathode.

Aspect 77. An electrochemical cell comprising the anode of any one of Aspect 68-Aspect 74.

Aspect 78. The electrochemical cell of any one of Aspect 75-Aspect 77, wherein peak power increases by from about 50% to about 300% compared to a baseline anode that is not coated.

Aspect 79. The anode of Aspect 78 wherein the peak power increases by from 100% to 200%.

From the foregoing, it will be seen that aspects herein are well adapted to attain all the ends and objects hereinabove set forth together with other advantages which are obvious and which are inherent to the structure.

While specific elements and steps are discussed in connection to one another, it is understood that any element and/or steps provided herein is contemplated as being combinable with any other elements and/or steps regardless of explicit provision of the same while still being within the scope provided herein.

It will be understood that certain features and subcombinations are of utility and may be employed without reference to other features and subcombinations. This is contemplated by and is within the scope of the claims.

Since many possible aspects may be made without departing from the scope thereof, it is to be understood that all matter herein set forth or shown in the accompanying drawings and detailed description is to be interpreted as illustrative and not in a limiting sense.

It is also to be understood that the terminology used herein is for the purpose of describing particular aspects only and is not intended to be limiting. The skilled artisan will recognize many variants and adaptations of the aspects described herein. These variants and adaptations are intended to be included in the teachings of this disclosure and to be encompassed by the claims herein.

Now having described the aspects of the present disclosure, in general, the following Examples describe some additional aspects of the present disclosure. While aspects of the present disclosure are described in connection with the following examples and the corresponding text and figures, there is no intent to limit aspects of the present disclosure to this description. On the contrary, the intent is to cover all alternatives, modifications, and equivalents included within the spirit and scope of the present disclosure.

### G. Examples

The following examples are put forth so as to provide those of ordinary skill in the art with a complete disclosure and description of how the compounds, compositions, articles, devices and/or methods claimed herein are made and evaluated and are intended to be purely exemplary of the disclosure and are not intended to limit the scope of what the inventors regard as their disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### 1. Materials and Methods

Commercially available, anode-supported solid oxide button cells were fabricated by Nexceris (Lewis Center, OH USA) were employed for the Examples described herein. The Nexceris cells used were composed of five layers as follows: starting from the anode: a ~400 μm thick Ni/YSZ cermet layer which supports the cell structure; a ~10 μm thick Ni/YSZ active layer; a ~5-10 μm thick YSZ electrolyte; a thin (2-3 μm), dense Gd-doped CeO2 (GDC) barrier layer, a ~5-10 μm thick LSCF/GDC active layer; and a 20 μm thick, pure LSCF current collecting layer. The cell-active area (limited by the cathode) was 1.266 cm². The exposure area of the anode to fuel was about 3.5 cm².

To specifically evaluate the impact of ALD coating on the anode, it was imperative that the cathode is well protected and sealed during the ALD processing so that it remains uncoated by the ALD procedure. In these experiments, the cell cathode was covered during the deposition using a Swagelok 1-inch VCR fitting (316 Stainless Steel VCR Face Seal Fitting, 1 in. Cap Part #: SS-16-VCR-CP and 316 Stainless Steel VCR Face Seal Fitting, Male NPT Connector Body, 1 in. VCR×1 in. MNPT Part #: SS-16-VCR-1-16, Swagelok Co., Solon, Ohio) and mica washers (Asheville-Schoonmaker Mica Co. 900 Jefferson Ave. Newport News, Virginia), and effectively blocked the cell cathod from exposure to ALD precursors. The ALD coating procedure was carried out in a commercial GEMStar-8 ALD reactor (Arradiance, LLC, Littleton, Massachusetts). ALD precursors were purchased from Strem Chemicals, Inc. (Newburyport, Massachussetts). Bis(ethylcyclopentadienyl)manganese (min. 98%) was utilized as an ALD precursor for MnOₓ ALD coatings. (Trimethyl)methylcyclopentadienylplatinum (IV), (99%) and the deionized water were used as Pt precursors and oxidants for depositing the Pt layer.

A first cell type studied in the Examples herein comprised a conformal MnOₓ nano-coating having a unary layer on a Ni/YSZ electrode. A second cell type studied in the Examples herein comprised a Pt—MnOₓ nanocomposite coating having two coating layers on a Ni/YSZ electrode. The MnOₓ nano-coating was deposited on an outer surface of the Ni/YSZ electrode using ALD deposition, i.e., a total of 50 ALD deposition cycles were performed for the MnOₓ layer, leading to an ALD coating having a thickness of ~20 nm MnOₓ. For the second cell type, the nano composite was deposited on an outer surface of the Ni/YSZ electrode, such that the nano-composite coating comprised an ALD coating of a MnOₓ nano-coating having a thickness of ~20 nm MnOₓ capping a subjacent conformal layer of ~3 nm Pt discrete nano-particles. The MnOₓ was deposite as in the first cell type over a Pt nanoparticle coating. The Pt nanoparticle was deposited by ALD methods using a total of 30 ALD deposition cycles. In other aspects, as additional examples of the those described herein, the composites can be layered in any manner deemed useful and/or convenient by the skilled artisan, e.g., a composite of Pt/MnOₓ could be two layers such as 5 nm Pt and 5 nm MnOₓ in layer thickness or multi-layers depostions, for example, 2 nm Pt, 5 nm, MnOₓ, and 3 nm Pt. Each of these and others are contemplated by the present disclosure.

To evaluate the impact of ALD coating Mn on the performance of the Ni/YSZ, the ALD coating was applied to a cell having a reduced anode (with Ni/YSZ in the anode) cell with neither surface pretreatment applied to the cells nor heat treatment was applied either before or after the ALD coating. Cell electrochemical operations were carried out after the ALD coating. The baseline and ALD coated cells were loaded at a constant current of 0.1 A cm-2 for several hours, and then the cyclic voltammetry and impedance data were collected at various times as indicated. The cell performance was examined using a TrueData-Load Modular Electronic DC Load, with voltage and current accuracies of 0.03% FS of the range selected +/−0.05% of the value. The cell impedance spectra were obtained using a Solartron 1287A potentiostat equipped with a Solartron 1260 frequency response analyzer (AMETEK Scientific Instruments, Oak Ridge, Tennessee). Impedance measurements were carried out using a Solartron 1260 frequency response analyzer in a frequency range from 50 mHz to 100 KHz. The impedance spectra and resistances (Rₛ and Rₚ) presented are those measured under a DC bias current of 0.3 A cm-2. For Nyquist plots, Rₛ is determined by the intercept at the higher frequency end, and Rp was determined by the distance between two intercepts.

After electrochemical operation, the ALD coated cells were sectioned and subjected to nanostructural and crystallographic examination using high resolution (HR) Transmission Electron Microscopy (TEM). All the TEM examinations were conducted in the cathode active layer. TEM samples were prepared by mechanical polishing and ion milling in a liquid-nitrogen-cooled holder. Electron diffraction, diffraction contrast, and HRTEM imaging were performed using a JEM-2100 transmission electron microscope operated at 200 kV. Chemical analysis was carried out under TEM using energy dispersive X-ray Spectroscopy (EDS).

### 2. ALD Coating of MnOₓ Layer on the Internal Surface of the Electrode Backbone

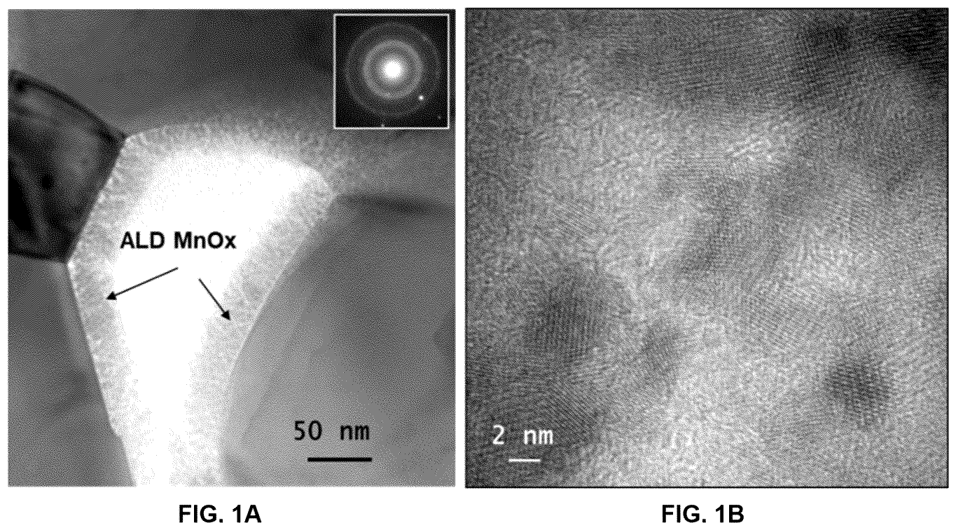

An exemplary ALD coating with a disclosed conformal, nanoporous MnOₓ layer is shown in the TEM images of FIGS. 1A-1B. The TEM images show that the ALD MnOₓ layer appears to be uniform and conformal with deep penetration of ~100 nm into the electrode pores (FIG. 1A), i.e., the ALD layer appears to be nanoporous. The random-orientated MnOₓ nanocrystals have a size of about 3 nm. The TEM images show that the MnOₓ nanocrystals appear to be loosely packed with the ALD layer, thereby providing porosity within the ALD layer (FIG. 1B). It should be noted that the electron diffraction rings (FIG. 1B) suggest the existence of very fine crystal grains within the ALD layer of as-deposited ALD coating. Although in this specific example the nanocrystals are about 3 nm in size, this size can be varied in other aspects of the present disclosure without departing from the overall intent and scope of the disclosure. For example, the nanocrystals could be from about 1 nm to about 50 nm, and any discrete size or range within the foregoing.

### 3. ALD Coating MnOₓ Layer and Resultant Decreased Resistance and Increased Power Density

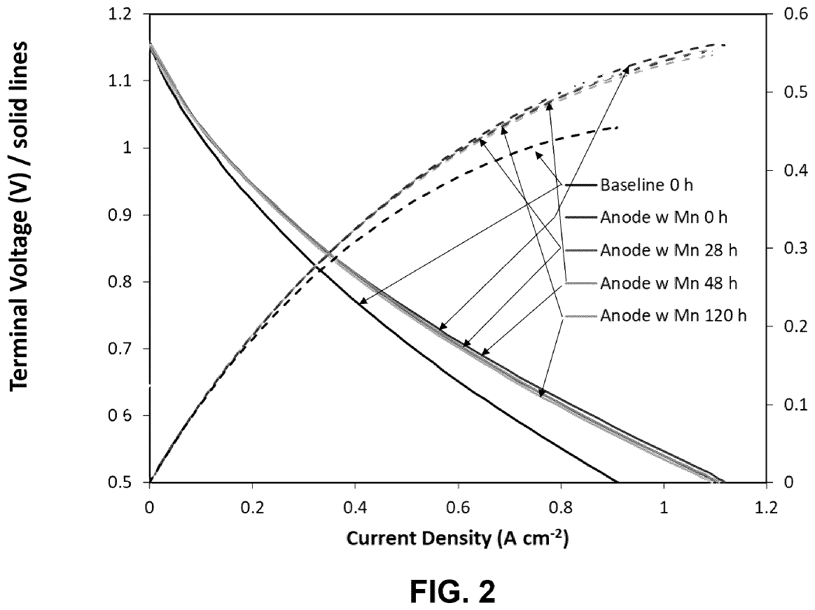

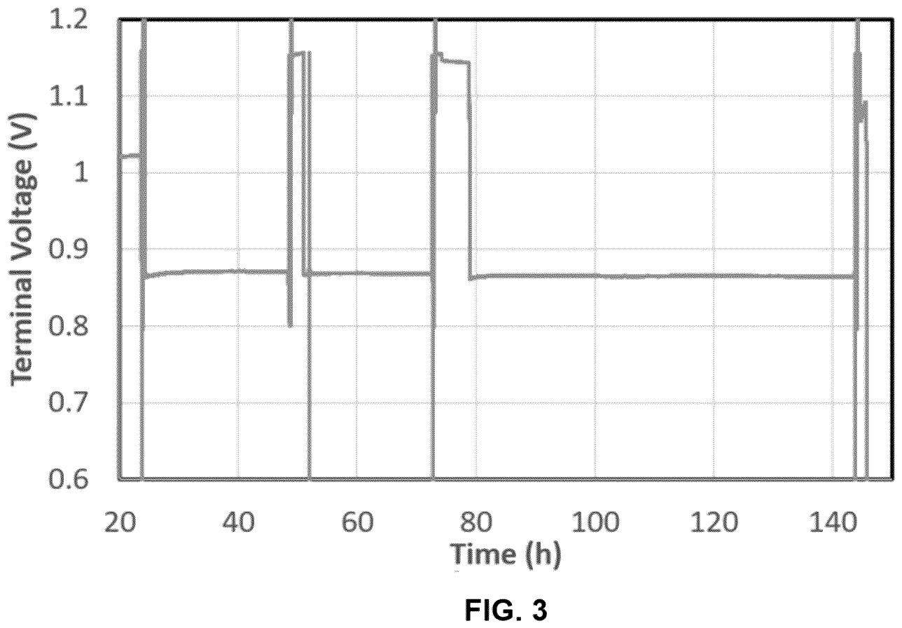

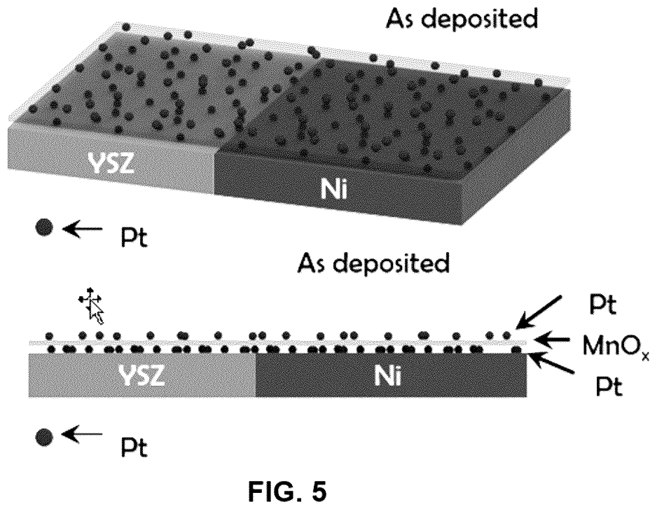

A LSM cell comprising an uncoated Ni/YSZ hydrogen electrode and a LSM cell comprising an ALD MnOₓ coated Ni/YSZ hydrogen electrode were each subjected to further electrochemical operation. In this context, the Ni/YSZ anode is being utilized as a hydrogen electrode or fuel electrode. The electrochemical operation was examined at 750° C. for both the LSM baseline or uncoated cell (i.e., no MnOₓ coating on the Ni/YSZ hydrogen electrode) and the coated LSM cell (i.e., having a MnOₓ coating on the Ni/YSZ hydrogen electrode). The active area for both the coated and the uncoated LSM cells was 1.266 cm². The uncoated LSM cell achieved an initial peak power density of 0.41 W cm⁻² at 750° C., whereas the coated LSM cell achieved a maximum power density of 0.547 W cm⁻² at 750° C. (FIG. 2). These data show a 1.33 enhancement factor for the coated LSM cell compared to the uncoated LSM cell under same operating conditions (see FIG. 2, FIG. 3 and Table 1). The data show that a coated LSM cell comprising a disclosed ALD MnOₓ coated Ni/YSZ fuel electrode exhibited both enhanced performance and stable performance enhancement (see FIG. 5). Moreover, the data that a coated LSM cell comprising a disclosed ALD MnOₓ coated Ni/YSZ fuel electrode demonstrated few power density changes upon continuous operation for 120 h at 750° C.

TABLE 1

| Cell | At Terminal voltage, V: | 0.5 | 0.6 | 0.7 | 0.8 |
|---|---|---|---|---|---|
| Baseline, 0 h | Current density, A cm⁻² | 0.791 | 0.576 | 0.413 | 0.282 |
| | Power density, W cm⁻² | 0.398 | 0.350 | 0.291 | 0.227 |
| ALD coated | Current density, A cm⁻² | 1.115 | 0.837 | 0.620 | 0.417 |
| cell, 0 h | Power density, W cm⁻² | 0.557 | 0.501 | 0.429 | 0.332 |
| ALD coated | Current density, A cm⁻² | 1.094 | 0.831 | 0.623 | 0.425 |
| cell, 120 h | Power density, W cm⁻² | 0.547 | 0.497 | 0.430 | 0.337 |

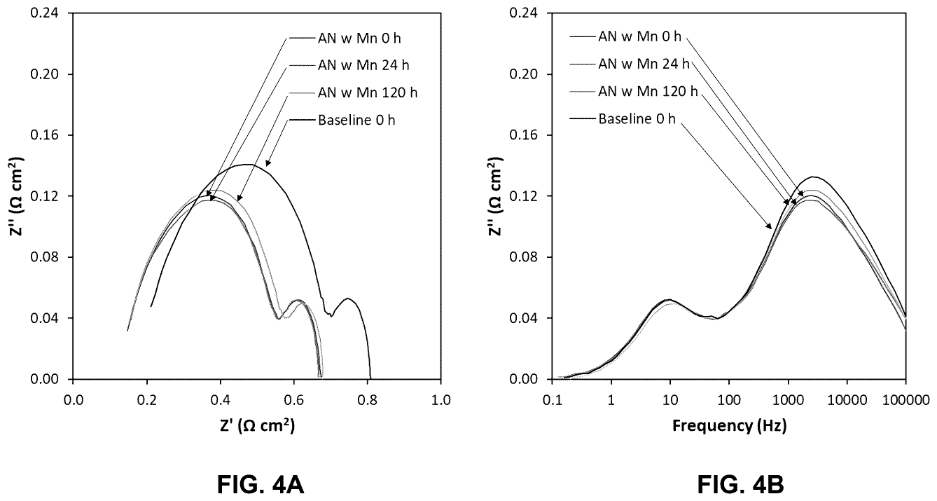

Although the ALD coating was applied to the Ni/YSZ hydrogen electrode that left the electrolyte and the oxygen electrode intact, the minimum ALD coating of the MnOₓ layer (~20 nm in thickness) did increase the conductivity and lower the resistance of the entire cell. The values for area-specific resistance (ASR) were obtained from the slope of the V-1 plot of each individual measurement for the electrochemical operation for coated and uncoated LSM cells (see FIG. 4 and Table 2). The uncoated LSM cell demonstrated an ASR value of 0.722 Ωcm² at 750° C., whereas the coated LSM cell comprising an ALD MnOₓ coating on the hydrogen electrode held an initial ASR value at 0 h of 0.574 Ωcm² at 750° C., which represents a decrease of about 19% compared to the ASR values of the uncoated LSM cell. These data further demonstrate that a cell comprising a MnOₓ ALD-coated electrode was associated with improved stability upon electrochemical operation. Consistent with the constant terminal voltage, the ASR value of the coated cell was nearly constant over a span of 120 h with a final value of 0.57 Ωcm² (0.6% lower compared to the initial ASR at 0 h), further illustrating the high stability of the cell comprising a MnOₓ ALD coated electrode.

TABLE 2

| | Max Power | Δ Power | ASR |
|---|---|---|---|
| Cell | (W/cm²) | (%) | (Ωcm²) |
| Coated cell, 120 h | 0.548 | 38% | 0.5707 |
| Coated cell, 48 h | 0.555 | 39% | 0.5727 |
| Coated cell, 28 h | 0.553 | 39% | 0.5755 |
| Coated cell, 0 h | 0.561 | 41% | 0.5741 |
| Uncoated cell, (baseline) | 0.398 | — | 0.722 |

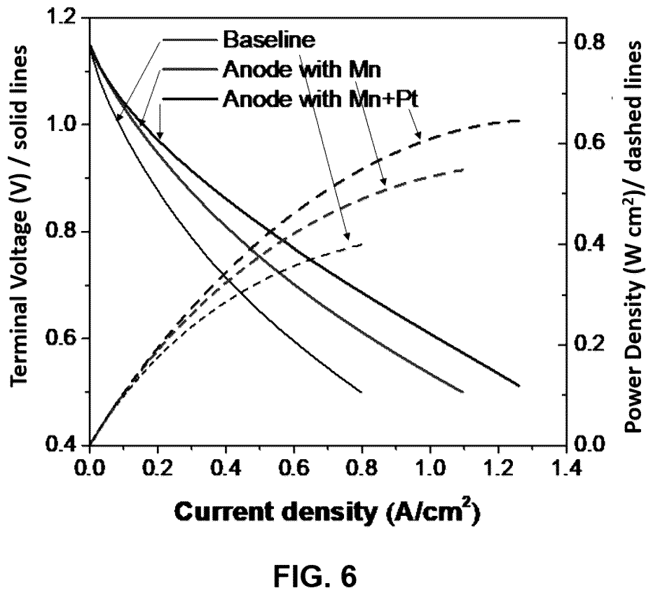

Impedance measurements were performed on both the coated and uncoated LSM cells. The impedance plots and data at 750° C. for the coated LSM cell and the coated LSM cell on the hydrogen electrode are shown in FIG. 6A, FIG. 6B, and Table 3, respectively. The impedance data were obtained using a current density of 0.3 A cm⁻².

TABLE 3

| | Rs | Change from Rs | Rt | Change from Rt | Rp | Change from Rp |
|---|---|---|---|---|---|---|
| Cell | (Ω cm²) | Baseline (%) | (Ω cm²) | Baseline (%) | (Ω cm²) | Baseline (%) |
| AN w Mn 0 h | 0.1202 | −30.5% | 0.6725 | −8.0% | 0.5522 | −1.0% |
| AN w Mn 24 h | 0.1262 | −27.1% | 0.6668 | −8.8% | 0.5406 | −3.1% |
| AN w Mn 48 h | 0.1260 | −27.2% | 0.6693 | −8.4% | 0.5433 | −2.6% |
| AN w Mn 120 h | 0.1295 | −25.1% | 0.6783 | −7.2% | 0.5488 | −1.7% |
| Baseline 0 h | 0.1730 | — | 0.7310 | — | 0.5580 | — |

As show in Table 4, consistent with a decreased ASR of the entire cell, analysis the impedance measurements indicated that both the series ohmic resistance and the polarization resistance were decreased due to the ALD coating of MnOₓ of the Ni/YSZ hydrogen electrode. It is noteworthy that the ~8% reduction of the total resistance of the entire cell had a minor contribution to the polarization resistance. On the other hand, reduction of the total resistance was dominated by a 30% reduction of the series resistance, thus implying a significantly increased conductivity (including both the electrical conductivity and the ionic conductivity) of the Ni/YSZ electrode that appears to be induced by a ALD coating of MnOₓ.

### 4. ALD Coating of Mn—Pt Composite onto the Internal Surface of Ni/YSZ Induced Increased Cell Power Density

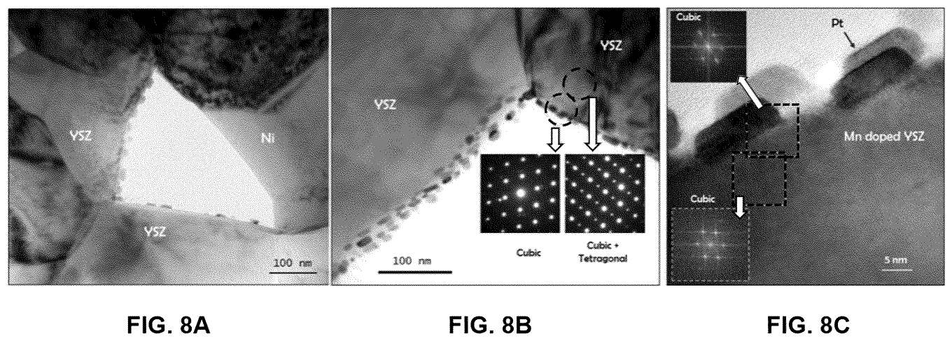

The foregoing data demonstrated the improved performance of a cell comprising a Ni/YSZ electrode comprising a unary MnOₓ coating (i.e., comprises an ALD coating of ~20 nm MnOₓ from 50 cycles of ALD deposition), and it was determined to assess a disclosed bi-layer ALD comprising Pt and MnOₓ bilayers, also referred to herein as a Mn—Pt nanocomposite (prepared as described above in Materials and Methods). The ALD coating of Mn—Pt nanocomposite, as described above, was provided by 50 deposition cycles of MnOₓ (having an aggregate coating thickness of ~20 nm) and 30 deposition cycles of Pt (having an aggregate coating thickness of ~3 nm comprising discrete Pt nanoparticles instead of the continuous layer for the ALD MnOₓ coating; see FIG. 8).

After 24 h operation at 750° C., the peak power density of a cell comprising a disclosed Mn—Pt nanocomposite was 0.41 W cm⁻² (for a cell with an uncoated Ni/YSZ electrode), 0.547 W cm⁻² (for a cell with a Ni/YSZ electrode comprising an ALD MnOₓ unary coating such as described in the previous Example), and 0.643 W cm⁻² (for a cell with a Ni/YSZ electrode comprising a ALD Mn—Pt nanocomposite coating). The peak power increased by 33% and 57%, respectively, for the cells with a Ni/YSZ electrode comprising an ALD MnOₓ unary coating and with a Ni/YSZ electrode comprising an ALD Mn—Pt nanocomposite coating (see Table 5). Table 4 shows Rs and Rp results. In Tables 4-5, “Baseline” refers to a cell comprising an uncoated Ni/YSZ electrode; “Mn-coat” refers to a cell with a Ni/YSZ electrode comprising an ALD MnOₓ unary coating; and “Mn—Pt coat” refers to a cell with a Ni/YSZ electrode comprising an ALD Mn—Pt nanocomposite coating.

TABLE 4

| Cell | Rs Ω cm² | Rp Ω cm² |
|---|---|---|
| Baseline | 0.173 | 0.558 |
| Mn-coat | 0.127 | 0.552 |
| Mn + Pt-coat | 0.160 | 0.466 |

TABLE 5

| | Max Power | Δ Power | Change from | ASR | Δ ASR | Change from |
|---|---|---|---|---|---|---|
| Cell | (W/cm²) | (%) | Power @0 h (%) | (Ωcm²) | (%) | ASR @0 h (%) |
| Baseline | 0.412 | — | — | 0.7223 | — | — |
| Mn-coat 96 h | 0.548 | 33% | −1.1% | 0.5885 | −19% | −1.6% |
| Mn-coat 77 h | 0.546 | 33% | −1.4% | 0.5924 | −18% | −1.0% |
| Mn-coat 26 h | 0.546 | 33% | −1.4% | 0.5752 | −20% | −3.8% |
| Mn-coat 0 h | 0.554 | 34% | — | 0.5982 | −17% | — |
| Mn + Pt-coat 137 h | 0.665 | 61% | +10.6% | 0.4913 | −32% | −7.9% |
| Mn + Pt-coat 100 h | 0.645 | 57% | +7.3% | 0.4963 | −31% | −7.0% |
| Mn + Pt-coat 17 h | 0.601 | 46% | 0.0% | 0.5530 | −23% | +3.6% |
| Mn + Pt-coat 0 h | 0.601 | 46% | — | 0.5336 | −26% | — |

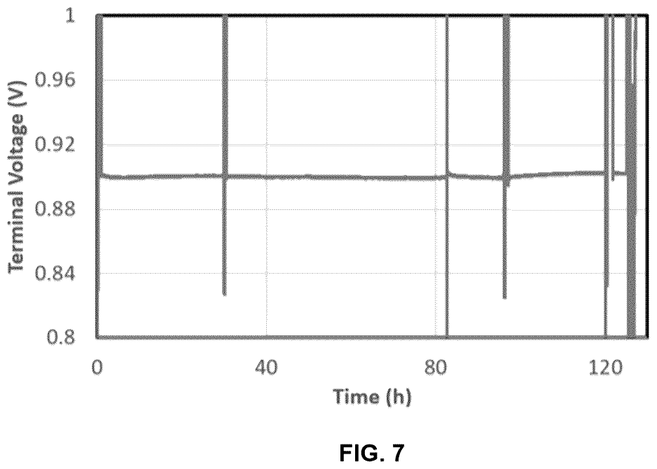

Moreover, the cell with a Ni/YSZ electrode comprising an ALD Mn—Pt nanocomposite coating displayed stable performance and there was substantially no terminal voltage change within 140 h (see FIG. 7). The data further show that the power density increase was accompanied by reduction of both the ohmic resistance and polarization resistance.

### 5. ALD Coating of Mn—Pt Composite onto the Internal Surface of Ni/YSZ Induced Spontaneously Pinning Nano-Catalysts

After 140 h operation, cell operation was terminated, and the cells were processed for TEM analysis. A representative TEM image of the Ni/YSZ anode of the operated cell is shown in FIGS. 8A-8C. TEM image and the EDS analysis show the distribution of Pt grains on the Mn-enriched YSZ surface. These figures show Pt discrete grains and the Mn-enriched YSZ surface with cubic structure (FIGS. 8A-8B). The YSZ grain surface possesses the cubic structure as shown in the diffraction pattern (FIG. 8B), and the YSZ grain matrix possesses a mixture of cubic and cubic+tetragonal as shown in the diffraction pattern (FIG. 8C). In a conventional fuel electrode Ni/YSZ, the nominal chemistry of YSZ is with 8% Y₂O₃ doping, and the YSZ crystal structure is a mixture of tetragonal and cubic (Ref. 12). It is noteworthy that in the present example, with the ALD nanocomposition coating of MnOₓ and Pt that the Pt appears to be on the YSZ grain surface only and appears to not affect the crystal structure of YSZ. Nevertheless, the surface layer (i.e., within about 10-20 nm of the surface) of the YSZ possesses a simple single cubic phase, as shown in both the diffraction pattern and the Fourier transformation of FIGS. 8A-8C (using the software provided by Gatan, Inc., Pleasanton, California, accompany the Gatan digital camera used in the micrograph analyses). EDS analysis shows that near the surface (i.e., within about ~10-20 nm of the surface), the YSZ is populated with Mn, with a ratio of Mn:Zr of about 0.375. Further beneath the outer surface (greater than about 10-20 nm), the YSZ is doped with Mn with a ratio of Mn:Zr of about 0.08. TEM images and EDS chemistry analysis show that Mn alloyed with YSZ grain changed the crystal structure of YSZ The data show that the MnOₓ coating provide a Mn-doped surface layer having a mixture of cubic and tetragonal YSZ to a near surface layer having a single phase YSZ with a cubic structure.

Distinct from the Mn ions that are alloyed with both Ni and YSZ grains, Pt presents a uniform and discrete nano-grains on the YSZ surface that is about 10 nm in size. Most impressively, the uniform and discrete Pt nanoparticles appear to be cuboid faceted and possess a well-defined crystal orientation relationship with the YSZ substrate, with all of the discrete Pt cuboids having the longer dimension of the cuboid parallel to the YSZ grain surfaces. These data suggest that instead of going through the random and irregular thermal agglomeration, upon the electrochemical operation at a high temperature of 750° C., the ALD coating of Pt experienced self-assembly into stable discrete nano cuboids that spontaneously grew on and pinned on the internal surface of the YSZ surface. These nano-sized discrete Pt have a very high surface area and are expected to possess high catalytic activity.

### 6. Discussion

In an aspect of the disclosure, the two different cells with ALD coating of MnOₓ on an Ni/YSZ surface consistently provide increased conductivity compared with the baseline (e.g., see Table 3 and Table 4). It is noteworthy that the thin ALD coating, i.e., a layer of ~20 nm MnOₓ coating on the Ni/YSZ fuel electrode alone, was associated with a 30% reduction of the Ohmic resistance of the entire cell. Without wishing to be bound by a particular theory, the as-deposited ALD layer of MnOₓ may be readily reduced to metallic Mn and form a Ni—Mn alloy. Distinct from Ni, which is catalytically active for both the reforming of methane and the deposition of carbon, Mn is not catalytic towards carbon formation.

Without wishing to be bound by a particular theory, it is believed that on the Ni surface, the Pt can be alloyed with Ni, thereby forming a capping layer. Pt—Ni is a catalyst with increased activity and stability and could provide the protection of Ni from oxidation and carbon coking. Nevertheless, the electrical conductivity of both Pt and Mn metals is lower than that of Ni. At 20 C, the conductivity is 1.43×10⁷ S/m for Ni; 6.94×10⁵ S/m for Mn; and 9.43×10⁶ S/m for Pt (Ref. 1). As such, the increased conductivity due to ALD coating on Ni/YSZ cannot be attributed to the increased conductivity from the Ni end. On the other hand, the data show that the Mn doped YSZ altered the surface layer having a simple cubic phase.

As evidenced from the performance of the state-of-the-art commercial cells with an LSM/YSZ cathode, YSZ with ~3% Mn solubility has been shown to be a cubic structure and possesses excellent ionic conductivity in the LSM/YSZ cathode. It was previously reported that Mn appears to have a level of about 3% in the YSZ grains for all commercially available state-of-the-art LSM/YSZ composite cathode (Ref. 22). For an LSM/YSZ cathode, Mn in YSZ is diffused from the adjacent LSM grain. The ~3% saturation level of Mn in YSZ (Ratio of Mn:Zr=0.05) appears to be established upon the high temperature (>1150° C.) sintering of SOFC composite cathodes. The saturation level is kept unchanged over the extended operation at 800° C. For the YSZ grain surface, the crystal structure changed from cubic to tetragonal, thus attributed to the increased conductivity due to the ALD coating of the MnOₓ on the internal surface of Ni/YSZ electrode.

It is understood that YSZ only possesses ionic conductivity, and a YSZ surface only serves as the ionic pathway and is inactive for electrochemical reactions. To introduce an active triple phase boundary (TPB) site, the introduction of the electronic pathways on ionic conducting YSZ surfaces is indispensable. Without wishing to be bound by a particular theory, it is believed that an Mn-enriched YSZ surface possesses both ionic conductivity and electronic conductivity. For example, it was recently reported that Mn doping YSZ in YSZ/LSM air electrode “reduced Mn cations spread out on the YSZ surface, leading to further enhancement of the electrochemical activity as the Mn-enriched YSZ/O₂ 2PB effectively become active for direct oxygen incorporation” (see Ref. 22). It should be noted that Ref. 22 refers to oxygen electrodes (cathode of a fuel cell), whereas the present disclosure relates surprisingly to fuel electrode of a fuel cell. As understood by the skilled artisan, the oxygen and fuel electrodes of a fuel cell are fundamentally distinct and present distinct concerns and fabrication concerns.

The increased ionic conductivity, especially the increased electrical conductivity induced by Mn doping of YSZ is essential for the activation of Pt catalysts that are pinned on the YSZ surface that is doped with Mn. In this context, the Pt nano-particles and their vicinity become active electrochemical reaction sites and significantly decrease the polarization resistance and increase the power density of the cell. The introduction of the electrical conductivity and the further activation of the Pt particles on the YSZ surface induced by Mn doping is fully supported by the decreased polarization resistance and the increased power density of the cell with the coating of MnOₓ and Pt, e.g., as shown in Table 4.

A concern for the ALD coating of the nano-catalysts on a porous electrode of SOC is thermal instability and the possible agglomeration of the ALD layer. However, the data herein show that the disclosed ALD coating comprising a MnOₓ—Pt nanocomposite is uniform, and Pt nanoparticles have a defined orientation relationship with YSZ grains. As such, the ALD coating of Pt provides spontaneous pinning of stable Pt nanoparticles on YSZ surfaces.

It will be apparent to those skilled in the art that various modifications and variations can be made in the present disclosure without departing from the scope or spirit of the disclosure. Other aspects of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

1. A coated electrode comprising:
an electrode comprising a nano-coating;
wherein the nano-coating comprises a first coating layer;
wherein the first coating layer comprises a continuous conformal layer comprising MnOₓ;
wherein the first coating layer penetrates the electrode.

2. The coated electrode of claim 1, wherein the first coating layer has a thickness from about 1 nm to about 500 nm.

3. The coated electrode of claim 1, wherein the first coating layer penetrates the surface of the electrode to a depth from about 1 nm to about 30 nm.

4. The coated electrode of claim 1, wherein the electrode is a Ni/YSZ electrode or a fuel electrode comprising a redox stable oxide.

5. The coated electrode of claim 4, wherein the electrode is a Ni/YSZ electrode.

6. The coated electrode of claim 4, wherein the first coating layer penetrates the surface of the electrode to a depth from about 1 nm to about 30 nm; and wherein within the depth of penetration there is a penetrated ratio of Mn:Zr of from about 0.1 to about 0.5.

7. The coated electrode of claim 6, wherein beneath the depth of penetration of the first coating layer, the Ni/YSZ electrode has a doping ratio of Mn:Zr less than or equal to about 0.15.

8. The coated electrode of claim 3, wherein the first coating layer penetrates the surface of the electrode to a depth of about 1 nm to about 30 nm; wherein the depth penetrated by the first coating layer comprises YSZ or an oxide conductor and MnOₓ; and wherein the depth penetrated by the first coating layer comprises an altered crystal structure compared to untreated YSZ or oxide conductor that lacks a first coating layer.

9. The coated electrode of claim 8, wherein the depth penetrated by the first coating layer comprises a cubic crystal structure.

10. The coated electrode of claim 8, wherein the untreated YSZ or oxide conductor that lacks a first coating layer has a cubic/cubic+tetragonal crystal structure.

11. The coated electrode of claim 1, wherein the coated electrode further comprises a second coating later; wherein the second coating layer is subjacent to the first coating layer; wherein the second coating layer comprises Pt; and wherein the second coating layer has a thickness of about 0.5 nm to about 10 nm prior to the coated electrode being operated in a cell comprising the coated electrode.

12. The coated electrode of claim 11, wherein the coated electrode comprises discrete nanoparticles of Pt superjacent to the first coating layer after the coated electrode is operated in a cell at about 300° C. to about 1200° C.; and wherein the discrete Pt nanoparticles are about 1 nm to about 10 nm in the longest dimension.

13. The coated electrode of claim 12, wherein the discrete Pt nanoparticles have a cuboid geometry.

14. The coated electrode of claim 11, wherein a coated cell comprising an anode has an increase in peak power of at least about 5% compared to a conventional cell; and wherein the conventional cell is identical to the coated cell except that it comprises an anode without the first coating layer or comprising the first coating layer and second coating layer.

15. The coated electrode of claim 14, wherein the coated cell comprising an anode has an increase in the peak power of from about 5% to about 1000% compared to a conventional cell.

16. The coated electrode of claim 1, wherein a coated cell comprising an anode has a terminal voltage that changes by less than or equal to about 10% when comparing the initial terminal voltage to a terminal voltage of at least 100 h of operation at a constant current density of 0.3 A cm⁻².

17. An anode comprising an atomic deposition layer of single phase YSZ or oxide conductor comprising a top surface and a bottom surface wherein the layer of single phase YSZ or oxide conductor is doped with manganese atoms wherein the ratio of manganese to zirconium atoms increases from the bottom surface to the top surface from about 0.05 to about 0.4.

18. The anode of claim 17 wherein the single phase is a simple cubic phase.

19. The anode of claim 17 further comprising platinum atoms pinned to the top surface.

20. An electrochemical cell comprising the electrode of claim 1 or the anode of claim 17.
